(19) United States
(12) Patent Application Publication
(10) Pub. No.: US 2009/0120497 A1
(43) Pub. Date: May 14, 2009

(54) METHOD OF METALLIZING SOLAR CELL CONDUCTORS BY ELECTROPLATING WITH MINIMAL ATTACK ON UNDERLYING MATERIALS OF CONSTRUCTION

(76) Inventor: Robert A. SCHETTY, III, Laurel Hollow, NY (US)

Correspondence Address: WINSTON & STRAWN LLP;PATENT DEPARTMENT, 1700 K STREET, N.W., WASHINGTON, DC, 20006, US

(21) Appl. No.: 12/267,257

(22) Filed: Nov. 7, 2008

Related U.S. Application Data
(60) Provisional application No. 60/986,971, filed on Nov. 9, 2007.

(51) Int. Cl. H01L 31/00; C25D 7/12

(52) U.S. Cl. 136/256; 205/157

(57) ABSTRACT

The invention relates to a metallized solar cell and the method of making thereof that includes depositing a metal or metals such as silver, nickel, copper, tin, indium, gallium, or selenium or their alloys on solar cells in a manner to form more substantial and robust electrical contacts that can carry current more efficiently and effectively or to provide the active layers required to convert sunlight into electricity. These deposits also protect the underlying metallic materials from corrosion, oxidation or other environmental changes that would deleteriously affect the electrical performance of the cell. The invention also relates to the use of specialized electroplating chemistries that minimize residual stress and/or are free of organic sulfonic acids to minimize chemical attack on solar cell substrates or prior metallizations that include organic and/or inorganic binders or related materials for depositing the initial metallic portions of the cell.

### CROSS-REFERENCE TO RELATED APPLICATIONS

This application claims the benefit of U.S. application 60/986,971 filed Nov. 9, 2007, the entire content of which is expressly incorporated herein by reference thereto.

### FIELD OF INVENTION

The present invention relates to a method for enhancing solar cell performance by improving electrical conductivity and electron flow and providing overall protection from chemical attack to the underlying materials of construction of the solar cell panel. In particular, the invention contemplates depositing a metal or metals such as silver, nickel, copper, tin, indium, gallium, or selenium or their alloys on solar cells in a manner to form more substantial and robust electrical contacts that can carry current more efficiently and effectively or to provide the active layers required to convert sunlight into electricity. These deposits also protect the underlying metallic materials from corrosion, oxidation or other environmental changes that would deleteriously affect the electrical performance of the cell. The invention also relates to the use of specialized electroplating chemistries that minimize chemical attack on solar cell substrates or prior metallizations that include organic and/or inorganic binders or related materials for depositing the initial metallic portions of the cell.

### BACKGROUND OF THE INVENTION

Panels used to collect and convert solar energy into electricity (“solar cells”) can be fabricated using a wide variety of manufacturing methods. In general the common elements of a solar cell panel manufacturing include (1) a substrate material (2) a layer/layers of material(s) which collect the solar radiation from sunlight coming into contact with the cell and convert it to electrical current; and (3) contacts or “conductors” to carry the electrical current from the solar panel to the destination source where it is converted into useful electricity for electrical power usage.

Silicon is the most commonly used material for solar cell panel manufacturing, and a typical construction is illustrated in FIG. 1. After fabrication, which can occur through a variety of generally known methods, the solar cell contacts must be formed, whereby a full area metal contact is made on the back surface, and a grid-like metal contact made up of fine “fingers” and larger “busbars” is screen-printed onto the front surface. The contacts or conductors as they are also known, are most commonly formed using a conductive metal paste consisting of Al, Ag, Al/Ag, or others. These are usually placed on different sides of the cell, i.e., the front side and the back side, but the conductors may also be placed on the same side of the solar cell depending on design specifications. They are often placed on the back side so that the front side of the cell can be placed to receive maximum direct exposure of sunlight. The metallic conductive paste used to form these conductors is then fired at several hundred ° C. to form metal electrodes in ohmic contact with the silicon. Most pastes typically form a “glass frit” at the interface with the silicon substrate after firing. After the solar cell conductors are formed, multiple solar cells are then interconnected in series (and/or parallel) by flat wires or metal ribbons, and assembled into modules or “solar panels”. The finished solar panel product typically has a sheet of tempered glass on the front, and a polymer encapsulation on the back to protect it from the environment.

Alternatively, glass or other non-silicon “thin film” materials can be used as the substrate material, for reasons of cost, efficiency, and/or application effectiveness. In one such example shown in FIG. 2, the substrate (glass) is covered by layers of copper (Cu), indium (In), gallium (Ga), and selenide (Se) as well as molybdenum (Mo) or other metals. This method is commonly known as the “CIGS” method of manufacturing solar panels which is an acronym based on the first letters of each of the elements of the metal layers or metal “stack” used in the sequence (Cu, In, Ga, Se). Conventionally, the metal layers are applied through “dry” deposition methods such as physical vapor deposition (PVD) and chemical vapor deposition (CVD), but these dry deposition methods require very specialized equipment and materials which are costly to implement commercially. Furthermore, dry deposition processes are very time consuming especially when applying relatively thick metallic layers, e.g., several microns which are required for the conductor metallization operation. Therefore, electroplating becomes a more desirable method of depositing the metal elements for reasons of cost and mass production feasibility.

One drawback of the use of the construction materials in the CIGS method, however, is that such materials can easily be chemically attacked by immersion in conventional electroplating solutions. Certain solutions negatively affect the adhesion of the conductor to the substrate and result in “lift-offs” which break the electrical connectivity of the cell, resulting in failures of the solar cell. Similarly, the glass frit at the silicon/conductive paste interface formed using the silicon substrate solar cell manufacturing method is readily attacked by a wide variety of chemical compounds. In addition, the electrodeposits in solar cell metallization applications must be significantly free of residual stress. High stress values can cause the deposit to contract upon itself during or immediately after plating, which can initiate adhesion failures and lift-offs, as residual stress is relieved through the contraction process. Thus, in general there is a need in the industry for improved metallization methods.

One of the most important properties of a solar cell is its electrical efficiency, i.e., a measurement of the amount of solar energy that the cell is capable of converting into useful electricity with the highest value being a theoretical 100%. The efficiencies of current commercial solar cells are typically in the range of 5-25%, depending on the type of substrate material. Solar cells based on silicon are typically in the higher end of that range (15-25%) while other substrate types such as organic substrates, are in the lower end of that range (5-15%).

Another factor that significantly affects the solar cell efficiency is the conductivity of the conductor materials. Currently, most conductive pastes used to form the conductors are porous containing typically 30-40% vacancies or open spaces, and these detrimentally affect the conductivity of the conductor to reduce solar cell efficiency. Thus, there is a need in the industry to improve the conductivity of the conductors in such solar cells.

### SUMMARY OF THE INVENTION

The present invention now satisfies the needs of the industry by applying additional layers of metals, such as silver, nickel, copper and tin, by electroplating upon an initial conductive layer, typically a conductive paste, to improve the conductivity and efficiency of the solar cell.

In one embodiment, a metallized solar cell having enhanced electrical conductivity or electrical efficiency is provided. This cell comprises a substrate that has electroplatable conductors comprising an initial conductive metallic layer on the substrate and non-electroplatable portions; and one or more additional metal layers upon the initial conductive solar cell material to improve conductivity and increase electron or current flow, as well as reduce, minimize or prevent corrosion or oxidation of the initial conductive solar cell conductor material. Optionally, an organic protective coating is included to minimize oxidation or other surface reactions from occurring on the conductive metallic layer or additional metal layer(s). The initial conductive layer is typically a silver paste comprising greater than 50% to 100% by weight silver and having a thickness of about 1 to 30 microns, or it can be a deposited metal layer, while the one or more additional metal layers comprise silver, nickel, copper, tin, indium, gallium, selenide or alloys or combinations thereof. The initial conductive layer is applied by a metallization method comprising conductive metal paste screening, physical or chemical vapor deposition, or electroless or electrolytic plating depending upon the preference of the manufacturer.

Another embodiment of the invention relates to a method for making the metallized solar cells disclosed herein so that the cells possess enhanced electrical conductivity and/or electrical efficiency. This method comprises applying an initial conductive layer on the solar cell substrate by a metallization method to form electroplatable portions thereof, and electroplating one or more additional metal layers upon the electroplatable portions of the substrate using cyanide-free electroplating solutions that are free of organic sulfonic acids. If desired or necessary, an organic coating can be optionally applied on the final metal layer to protect the electroplatable portion of the substrate. In these methods, the electroplated layers are preferably provided by cyanide-free electroplating solutions that are free of organic sulfonic acids to avoid “lift-offs” of the layers which break the electrical connectivity of the cell.

Yet another embodiment of the invention is a method of enhancing the electrical conductivity or electrical efficiency of a solar cell which comprises providing electroplated metal layers that are significantly free of residual stress on a solar cell substrate thereon to form more substantial current carrying metal deposits, wherein the residual stress of the metal layers is no more than about 12,000 psi to bonding of the layers and minimize loss of electrical connectivity. The residual stress in the electroplated metal layers is no more than about 8000 to 9000 psi.

In these embodiments, a preferred type of solar cell is a “CIGS” solar cell that includes layers of copper (Cu), indium (In), gallium (Ga), and selenide (Se) and optionally molybdenum (Mo) or other metals.

### BRIEF DESCRIPTION OF THE DRAWINGS

FIG. 1 shows a typical silicon solar cell panel containing front contact (11), a-SiN:H (AR coating and passivation) (12), c-Si wafer (13) comprising n-type (emitter) (15) and p-type (absorber) (16), and back contact (14).

FIG. 2 shows a solar panel with glass as the substrate (26) which is covered by layers of ZnO (front contact) (21), CdS (22), metal absorber (23) comprising copper (Cu), indium (In), gallium (Ga) and selenide (Se), and molybdenum (Mo) (back contact) (24) and SiO_{X} (barrier) (25).

FIG. 3 shows a spiral contract meter for measuring residue stress of the electroplated deposits.

FIGS. 4, 5 and 6 are photomicrographs of various deposits on solar panels, with FIG. 6 illustrating the invention and FIG. 4 and 5 illustrating prior art deposits.

FIGS. 7, 8 and 9 are graphs of resistance before and after electroplating for various deposits.

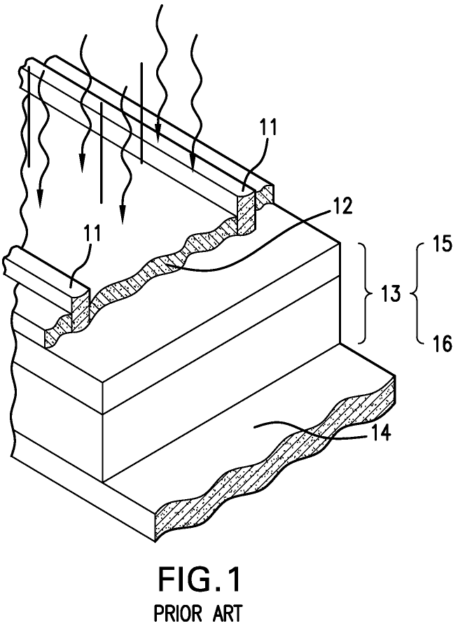

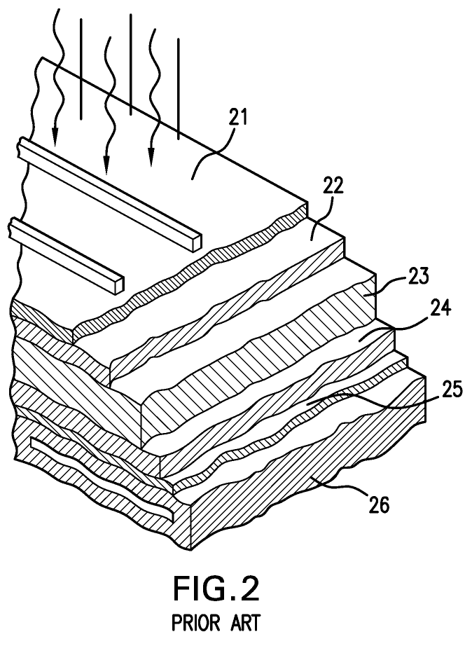

### DETAILED DESCRIPTION OF THE PREFERRED EMBODIMENTS

In a silicon solar cell, an initial conductive layer is applied onto the front or back of the silicon substrate by a metallization method such as conductive metal paste screening to form electroplatable portions of the substrate. It has now been identified that applying additional layers of metals, such as silver, nickel, copper and tin or their alloys, on top of or upon the conductive paste by electroplating can improve the conductivity and increase electron or current flow, thus enhancing efficiency of the solar cell. The additional metal layers can be deposited on top of the existing conductive metal paste or in some cases these layers can partially or completely replace the conductive metal paste. In fact, other metallization techniques can be used for the initial layer upon which the additional metal layers are deposited.

Although metallization of solar cell conductors by electroplating is desirable due to ease of use, cost benefits, and relatively quick deposition times, the conductive metal paste used as the foundation of the conductor can easily be chemically attacked by immersion in the electrolytes used to subsequently electroplate the conductors. In addition, deposits that are plated onto (or in place of) the conductive paste which possess high levels of residual stress values, such as between 12,000 and 20,000 psi, can contract upon themselves. Both of these issues can negatively affect the adhesion of the conductor to the substrate, thus resulting in reduced solar cell performance and efficiency.

The present method enhances electrical efficiency of a solar cell by the deposition by electroplating of additional metal layers that are significantly free of residual stress. The term “significantly free or residual stress” means that the stress is present at a value that is low enough to avoid interfering with deposit adhesion. Preferably, the residual stress is less than 12,000 psi and most preferably it is no more than 8000 to 9000 psi. In addition, these layers are plated using electroplating chemicals that are free of organic sulfonic acids, such as phenolsulfonic and alkylsulfonic acids, which acids attack the conductive metal pastes used as the main conductor starting material. The term “free of organic sulfonic acids” means that no such acids are present or that, if present, are at a concentration that is insufficient to attack the conductive metal pastes that may be used.

The substrates that are electroplated by the present method are solar cells that include both electroplatable conductors comprising an initial conductive layer and non-electroplatable portions. The initial conductive layer contains an initial conductive solar cell conductor metallization material that is either silver or other metals, which is applied by conductive metal paste screening, physical or chemical vapor deposition, or electroless or electrolytic plating. Although conductive metal paste screening is the most common method, the initial conductive layer may not contain conductive paste at all. Instead, it may be applied by suitable activation of the substrate followed by electroless metal deposition. Regardless of the type of initial conductive layer applied, in all cases the deposition of additional metal layers increases the amount of metal that is initially deposited to improve conductivity and increases electron or current flow, and therefore enhances solar cell efficiency. The metallization of the conductors through electroplating is provided only upon the electroplatable portions on top of or upon the initial conductive solar cell conductor metallization material.

In one embodiment of the invention, the additional metal layers applied include silver, nickel, copper, tin or alloys thereof. When the initial conductive layer is applied to the front of the substrate, the additional metal layers can comprise silver alone, but when the initial conductive layer is applied to the substrate, the additional metal layers need to be solderable and for that reason usually comprise multiple layers such as tin-nickel-copper-silver, tin-nickel-copper or other alloys or combinations of these materials. Copper is a desirable metal layer due to its high conductivity, but it does not have sufficient corrosion resistance so that it should be coated with a layer of a more resistant metal, such as silver or tin. Other combinations of layers can be used depending upon the particular installation and desired results. Besides improving conductivity and increasing electron and current flow, the additional metal layers also enhance electrical conductivity or electrical efficiency by reducing chemical attack or oxidation. In some applications, an organic coating may be applied as a protective coating to minimize oxidation and other surface reactions from occurring on the final metal layer applied which reactions could degrade the performance of the cell. An initial metal layer can be deposited by any one of a variety of generally known techniques, including physical vapor deposition, chemical vapor deposition, or by electroless or electrolytic plating.

After generating the initial metal layer, the additional metal layers, in some cases, are deposited on top of or upon the existing layer. Although conductive metal paste has been used extensively, it can be replaced partially or completely by the initially deposited metal layer.

In one embodiment of the invention, the solar cell is made of a silicon substrate and is provided with an initial conductive solar cell conductor metallization material having a thickness of about 0.01 to 200 microns, preferably 0.5 to 100 microns, and most preferably 1 to 30 microns. Any of a wide range of metals can be deposited, but a preferred initial conductive solar cell conductor metallization material comprises greater than 50% to 100% by weight silver and is provided by conductive metal paste screening, physical vapor deposition, chemical vapor deposition, or by electroless or electrolytic plating.

In one embodiment of the invention, when multiple metal layers are used, the additional metal layers of the solar cell comprise a nickel layer having a thickness of 0.01 to 20 microns, preferably 5 to 10 microns, a copper layer having a thickness of 0.01 to 100 microns, preferably 5 to 25 microns; a tin layer having a thickness of 0.01 to 200 microns, preferably 5 to 10 microns, or alloys, or combinations of these with or without other metal layers.

The conductive portions of the solar cell can be protected by the application of one or more metal layers to obtain the desired performance improvements, such as the build-up of the metal layer by electroplating to provide additional metal for a larger, more secure footprint or the use of the deposited layer for rendering the conductive portions solderable for connection to other electrical components. To the extent that the deposited metal layer or underlying conductive portion is subject to oxidation, the deposited metal layer or underlying conductive portion can be further protected with a polymer coating or other organic compound that is applied by conventional techniques to minimize corrosion, prevent tarnish, discoloration or the formation of oxides which otherwise interfere with the electrical performance of the cell.

Adhesion of the metal to the conductor as well as the adhesion of the conductor to the substrate can be checked by a simple tape test known in the art, such as the IPC-TM-650 Test Method. In particular, the test method requires a roll of pressure sensitive self-adhesive film tape 1.3 cm (0.5 in) wide exhibiting an adhesive strength of at least 44 N/100 mm (40 oz-force/in) but no more than 66 N/100 mm (60 oz-force/in) as tested per ASTM D3330.

The tape test is usually performed in the “as-plated” condition and/or after exposure to a variety of thermal and/or humidity environments. For example, exposure to 85° C./85% relative humidity (RH) for 500-1000 hrs is a common reliability test method in the solar cell manufacturing industry. After this heat and humidity exposure, tape is applied to the surface of the metallized conductor and then the tape is quickly removed. None of the metallized conductor material should be removed by this simple “tape test”, including the underlying conductive paste. However, it has been found that when electroplated deposits of silver, nickel, copper, tin, and other metals that possess high residual stress values are utilized, the electroplated metallized conductor fails the tape test. Similarly, when certain types of chemistries are used in the electroplating solutions for depositing silver, nickel, copper, tin, and other metals, the electroplated metallized conductor fails the tape test. This is particularly the case when the electroplating solutions contain organic sulfonic acids, such as phenolsulfonic or alkyl sulfonic acid, or other organic or inorganic compounds based on organic sulfonic acids.

The current invention has identified that by minimizing residual stress in the electroplated layers used to metallized solar cell conductors, and/or by avoiding certain types of chemistries in the electroplating solutions used to metallized solar cell conductors, these types of adhesion failures can be avoided. In particular, the avoidance of organic sulfonic acids in the plating solutions is beneficial. The organic sulfonic acids in the electroplating solutions chemically react with the compounds in the conductive paste, (e.g., aluminum, silver, inorganic or organic binding materials), the glass frit at the interface, or other compounds, during immersion in the electroplating solution, thus weakening the bond of the conductive paste/glass frit to the solar cell substrate. A conductive paste to substrate bond that is weakened sufficiently will exhibit partial or complete failure of the metallized conductor on the solar cell when the tape test is applied. By minimizing residual stress in the deposits and/or by eliminating detrimental chemicals such as organic sulfonic acids in the electroplating solutions, these types of adhesion failures can be minimized or completely avoided.

For silver plating of solar cell conductors, a silver cyanide electrolyte such as Techni Silver EHS-3 available from Technic, Inc., i.e., one that produces a silver deposit with very low residual stress and that is free of organic sulfonic acids, may be used. If the use of cyanide compounds and other compounds which are not environmentally friendly is not desired, a non-cyanide silver plating process can be used. In general, any non-cyanide silver cyanide organometallic complex bath which produces a deposit possessing a low residual stress value and/or which the plating chemistry is free of organic sulfonic acids can be used, such as the well known succinimide based non-cyanide baths of the prior art that are disclosed, for example, in U.S. Pat. No. 4,246,077. A preferred silver electroplating solution is disclosed in US Patent Application Publication No. 2005/0183961. This electroplating solution comprises silver in the form of a complex of silver with hydantoin or a substituted hydantoin compound; an excess (i.e., more than a stoichiometric amount based on the amount of silver) of the hydantoin or substituted hydantoin compound, together with an effective quantity of a non-precipitating electrolyte salt. The non-precipitating electrolyte salt may be any of the salts of sulfamic, nitric, glycolic, lactic acids, isonicotinic acid and its salts. Although 2,2′ dipyridyl can be added for the purpose of obtaining a mirror-bright to brilliant deposit it is not necessary to obtain a silver deposit that has the appropriate current carrying characteristics. The excess amount of the hydantoin or substituted hydantoin compound ensures the complete (or nearly complete) complexation of the silver. Also, if desired, a pyridine or substituted pyridine compound can be included for the purpose of improving the overall brightness of the deposit obtained. Advantageously, the electroplating solution further comprises an effective quantity of a surface-active agent when even further improvements in the overall brightness and brilliance of the deposit are desired. The preferred pyridine or substituted pyridine compound may be nicotinamide, isonicotinamide, 2-aminopyridine, 3-aminopyridine, nicotinic acid and its salts, or A surface-active material that is soluble in an alkaline bath may be added in certain situations and may be one or more of alkyl sarcosines (e.g., Hamposyl C, Hamposyl L, or Hamposyl O), salts of sulfonated naphthalene-formaldehyde condensates (e.g., Blancol or Blancol N), or sodium alphaolefin sulfonates (e.g. Rhodacal or Rhodacal N).

In addition to the preferred solution, other non-cyanide, no organic sulfonate bath solutions can be used, e.g., the bath chemistries of any of U.S. Pat. Nos. 4,126,524, 4,426,671, 4,478,691, and 5,601,696. To the extent necessary to understand these processes, the entire content of each cited document is expressly incorporated herein by reference thereto.

Similarly, the nickel, tin, copper, and other electroplated deposits used to electroplate solar cell conductors, and/or the electroplating solutions used to electroplate solar cell conductors should be free of organic sulfonic acids, such as phenolsulfonic and alkylsulfonic acids, in order to avoid technical issues such as adhesion failures. Also, cyanides or other undesirable compounds should also be avoided.

Some tin plating solutions that are useful in the present invention include, but are not limited to, those described herein. Tin and tin alloys are commercially plated from solutions with sulfate as the primary anion. See for example U.S. Pat. Nos. 4,347,107, 4,331,518 and 3,616,306. Other sulfate baths based on sulfuric acid but without environmentally undesirable additives are preferred. Due to the sensitive nature of many of the solar cell materials, a tin plating solution which operates at a near-neutral pH value would be preferred to further minimize chemical attack of underlying materials. A preferred near-neutral tin electroplating bath is disclosed in U.S. Patent Application Publication No. 2006/0113195. Again, the entire content of each cited document is expressly incorporated herein by reference to the extent necessary to understand the bath components that are disclosed in these documents.

Any one of a number of alloying elements can be added to the tin plating solution. These are primarily added in an amount such that less than 10%, preferably less than 7% and most preferably less than 5% of the alloying element is present in the deposit. Preferred alloying elements include silver (up to 3.5% of the deposit), Bismuth (up to 3% of the deposit), copper (up to 3% of the deposit) and zinc (up to 2% of the deposit). While other alloying elements can be used, it is generally not preferred to use those that may have an adverse effect on the environment, i.e., antimony, cadmium, and particularly lead. Preferably, the tin content of the deposit is as high as possible and is usually on the order of as high as 99% by weight or more with the balance being unavoidable impurities rather than intentionally added alloying elements.

In one embodiment of the invention, the solar cell substrate made of glass or other non-silicon “thin film” materials, and is covered by layers of copper (Cu), indium (In), gallium (Ga), selenide (Se) and optionally molybdenum (Mo) or other metals. The metal elements are deposited onto the substrate by electroplating using electroplating chemicals that are free of organic sulfonic acids, such as phenolsulfonic and alkylsulfonic acids, or other organic or inorganic compounds based on organic sulfonic acids, to avoid chemical attack and thus enhance electrical efficiency of the solar cell. In addition, these metal deposits should be significantly free of residual stress, preferably the residual stress is less than 12,000 psi and most preferably is no more than 8000 to 9000 psi, to avoid adhesion failures related to stress-relief of the deposits during or after plating.

Other metal deposition techniques can be used with the invention providing a further build-up of metal by an electroplating technique using electroplating chemicals that are free of organic sulfonic acids to enhance the thickness of the deposit to facilitate electrical connection of wire or other components, and/or by using electroplated deposits that are significantly free of residual stress, preferably the residual stress is less than 12,000 psi and most preferably is no more than 8000-9000 psi.

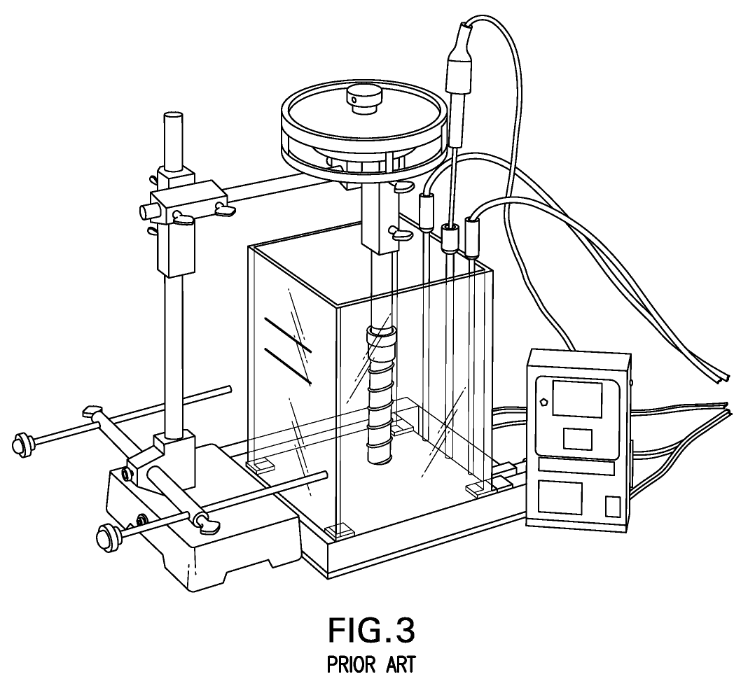

The residual stress of the electroplated deposits can be measured by a number of techniques. One way is to use a spiral contract meter in the arrangement shown in FIG. 3. Alternatively, a stress tab analyzer can be used for this purpose. When the stress tab analyzer is used to measure the deposit stress quantitatively, the test strip with one side coated is first secured on the jig. Then, the jig is placed in the plating cell which has two anodes. After plating, the jig is removed and rinsed. The reading on leg spread is the corresponding stress. Other techniques for measuring stress can be used if desired so long as the deposits are monitored or checked to assure that they are of low stress. The electroplating method that is used can be one that also contributes to low stress in the deposit. For example, the method includes avoiding brighteners or other bath additives that contribute to the level of stress in the deposit so that the desired residual stress values disclosed herein can be achieved.

### EXAMPLES

The following examples illustrate the most preferred embodiments of the invention.

### Example 1 (Comparative)

Silver was electroplated from an electrolyte containing methane sulfonic acid (MSA) onto a silicon solar cell substrate which had been previously metallized and fired with silver conductive paste. Silver was plated at 1 A/dm² for a period of time sufficient to obtain an average of 5 μm silver deposit thickness. The metallized solar cell was then subjected to heat and humidity aging at 85° C./85% RH for 1000 hrs, after which a simple tape test for adhesion was performed. The sample failed the tape test as the silver deposit and part of the conductive paste was removed during the tape removal.

### Example 2

Silver was electroplated from a commercial silver non-cyanide electrolyte which is also free of organic sulfonic acids (Technisol AG from Technic Inc.) onto a silicon solar cell substrate which had been previously metallized and fired with silver conductive paste. Silver was plated at 1 A/dm² for a period of time sufficient to obtain an average of 5 μm silver deposit thickness. The residual stress value of this deposit was approximately 4000 psi. The metallized solar cell was then subjected to heat and humidity aging at 85° C./85% RH for 1000 hrs, after which a simple tape test for adhesion was performed. This sample passed the tape test as none of the silver deposit or conductive paste was removed during the tape removal.

### Example 3

Silver was electroplated from a commercial silver non-cyanide electrolyte which is also free of organic sulfonic acids (Technisol AG from Technic Inc.) onto a silicon solar cell substrate which had been previously metallized and fired with silver conductive paste. Silver was plated at 1 A/dm² for a period of time sufficient to obtain an average of 5 μm silver deposit thickness. The residual stress value of this deposit was approximately 4000 psi. The metallized solar cell was then further processed through a post-treatment chemistry (Tarniban KS from Technic Inc.) which forms a thin, benign, protective organic coating on the silver deposit. The metallized solar cell with protective organic coating was then subjected to heat and humidity aging at 85° C./85% RH for 1000 hrs, after which a simple tape test for adhesion was performed. This sample passed the tape test as none of the silver deposit or conductive paste was removed during the tape removal.

### Example 4 (Comparative)

Silver was electroplated from a commercial silver non-cyanide electrolyte which is free of organic sulfonic acids (Technisol AG from Technic Inc.) but to which had been added an excessive amount of organic brightening agent to cause a residual stress value in the deposit of greater than 12000 psi. Silver from this electrolyte was deposited onto a silicon solar cell substrate which had been previously metallized and fired with silver conductive paste. Silver was plated at 1 A/dm² for a period of time sufficient to obtain an average of 5 μm silver deposit thickness. The metallized solar cell was then subjected to the heat and humidity aging at 85° C./85% RH for 1000 hrs, after which a simple tape test for adhesion was performed. This sample failed the tape test as the entire silver deposit and conductive paste were removed during the tape removal.

### Example 5 (Comparative)

Nickel was electroplated from an electrolyte containing methane sulfonic acid (MSA) onto a silicon solar cell substrate which had been previously metallized and fired with silver conductive paste, and plated with silver using the process listed in Example 1. Nickel was plated at 1 A/dm² for a period of time sufficient to obtain an average of 5-7 μm nickel deposit thickness. The metallized solar cell was then subjected to the heat and humidity aging at 85° C./85% RH for 1000 hrs, after which a simple tape test for adhesion was performed. This sample failed the tape test as the conductor metal was removed during the tape removal.

### Example 6

Nickel was electroplated from a commercial electrolyte which is free of organic sulfonic acids (Technisol Nickel LB from Technic Inc.) onto a silicon solar cell substrate which had been previously metallized and fired with silver conductive paste, and plated with silver using the process listed in Example 2. Nickel was plated at 1 A/dm² for a period of time sufficient to obtain an average of 5-7 μm nickel deposit thickness. The deposit was then subjected to the heat and humidity aging at 85 C/85% RH for 1000 hrs, after which a simple tape test for adhesion was performed. This sample passed the tape test as none of the conductor metal was removed during the tape removal.

### Example 7

Copper was electroplated from a commercial electrolyte which is free of organic sulfonic acids (Technisol Copper D-107 from Technic Inc.) onto a silicon solar cell substrate which had been previously metallized and fired with silver conductive paste, and plated with silver and nickel using the processes listed in Example 4. Copper was plated at 2 A/dm² for a period of time sufficient to obtain an average of 25 μm copper deposit thickness. The copper deposit had a residual stress value less than 12000 psi. The deposit was then subjected to the heat and humidity aging at 85 C/85% RH for 1000 hrs, after which a simple tape test for adhesion was performed. This sample passed the tape test as none of the conductor metal was removed during the tape removal.

### Example 8

Tin was electroplated from a commercial electrolyte which is free of organic sulfonic acids (Technisol Tin from Technic Inc.) onto a silicon solar cell substrate which had been previously metallized and fired with silver conductive paste, and plated with silver, nickel and copper using the processes listed in Example 5. Tin was plated at 4 A/dm² for a period of time sufficient to obtain an average of 10 μm tin deposit thickness. The deposit was then subjected to the heat and humidity aging at 85° C./85% RH for 1000 hrs, after which a simple tape test for adhesion was performed. This sample passed the tape test as none of the conductor metal was removed during the tape removal.

### Example 9

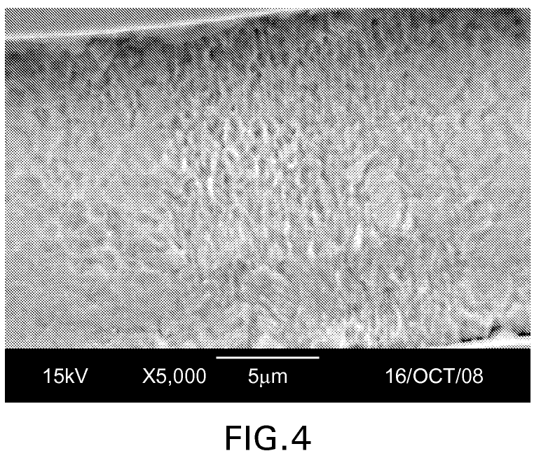

The grain structure of a typical silver deposit produced from a commercial cyanide-containing electrolyte is shown in FIG. 4. The deposit has a fine-grained, equiaxed deposit structure which produces desirable effects in the solar cell applications, yet the chemistry used to produce such a structure from a cyanide-containing electrolyte is not acceptable due to the presence of cyanide, an extremely dangerous, toxic chemical which is extremely hazardous to human health and safety.

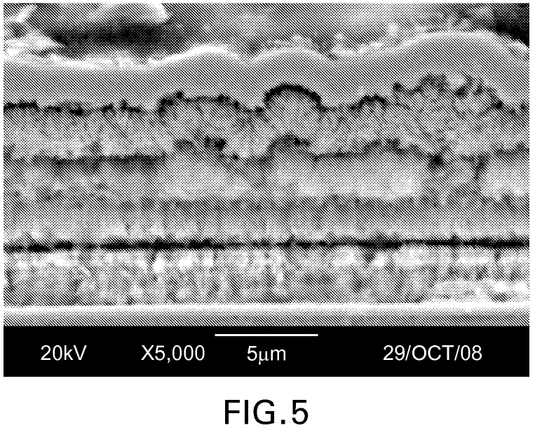

The grain structure from conventional, non-cyanide electrolytes, such as those of U.S. Pat. No. 6,620,304 B1 of Hoffacker or US patent application publication no. US2008/0035489 A1 of Allardyce et al. is shown in FIG. 5. Although these electrolytes are acceptable from a safety standpoint, the grain sizes of the resulting deposits are large and non-homogenous, and this type structure is considered undesirable because the large grain sizes lend themselves to lower efficiency gains during operation of the solar cell.

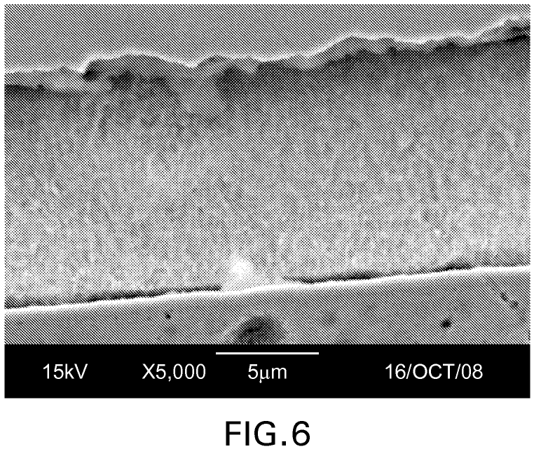

In contrast, the grain structure in deposits resulting from the non-cyanide preferred silver plating process of the present invention is shown in FIG. 6. This plating process produces a fine-grained, equiaxed grain structure, yet it is safely produced from a non-cyanide electrolyte. Such a system yields a deposit structure with high efficiency gains in the solar cell metallization application as described below. The process of the present invention is unique in that it produces a grain structure similar to the cyanide-containing electrolyte, yet it is free of cyanide and therefore perfectly acceptable in the solar cell manufacturing environment. The present invention provides the benefits of the cyanide-containing electrolyte in terms of the grain structure produced, without the negatives associated with the presence of cyanide.

The electrodeposition of silver on top of the front side silver paste is a way to improve the front side contact and increase cell efficiency. These results have shown cell efficiency for the deposit of FIG. 6 increases of up to 0.4% absolute. This type of improvement is advantageous and unexpected compared to the cell efficiencies of the deposits of FIGS. 4 and 5.

### Example 10

The following test cells were manufactured using a standard process. After firing, the cells went through a laser edge isolation and then electrical testing prior to the electrodeposition process.

The test cells were processed through a light induced plating (LIP) tool where light was introduced to the cell to generate some of the power needed for the electrodeposition process. A rectifier was used to put a voltage potential on the backside of the cell to protect the backside contact from becoming the anode and dissolving during the electrochemical reaction.

The test cells were electroplated in Technic's TechniSol® Ag silver plating bath for 10 minutes at room temperature. These conditions resulted in 8-10 microns of fine grain plated silver being deposited on top of the silver paste front side contacts. The silver metal was plated at a current density of 1.3 amps/decimeter² (ASD). Subsequent testing has shown this thickness can be achieved in 5 minutes if the solution temperature is raised to 40° C. and agitation is increased. This allows for plating to happen with a fine grain deposit at 2.6 ASD.

After the electrodeposition process, the cells were electrically tested again. Since the cells had been serialized, it was possible to look at the change in the electrical characteristics for each cell.

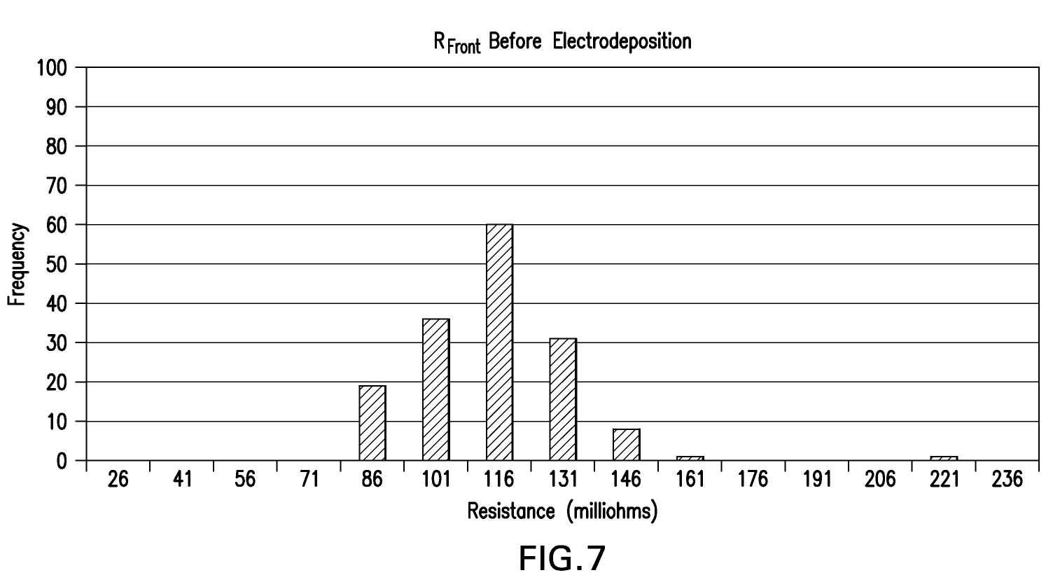

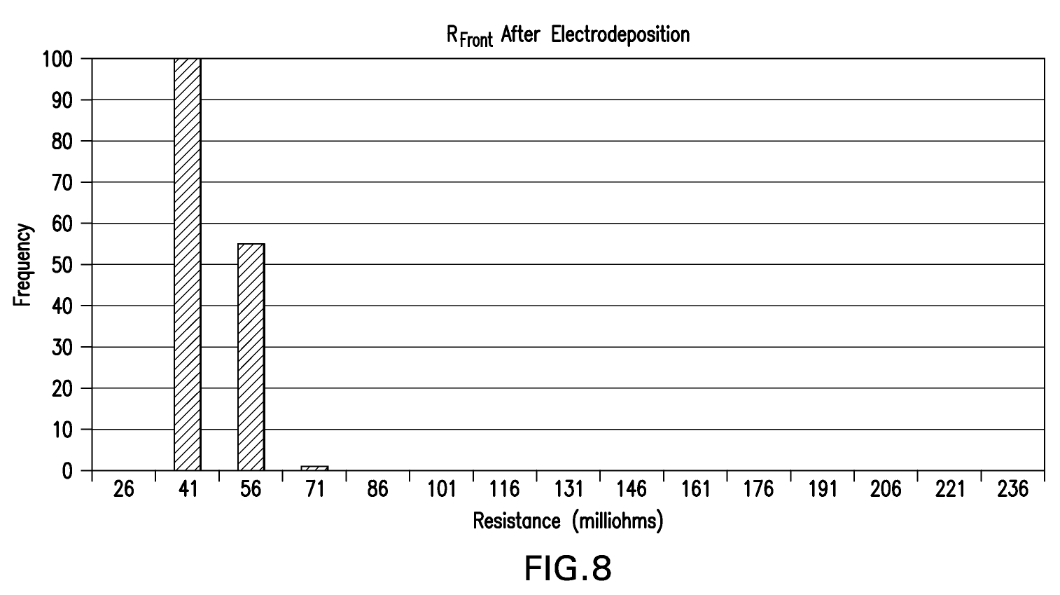

By depositing the silver metal onto the silver paste contacts according to the invention, the average R_{Front} was reduced dramatically. The batch of test cells started with an average R_{Front} of 122 milliohms (as measured from bus-bar to bus-bar) prior to the deposition of silver. After the plating process, the average R_{Front} was reduced to 54 milliohms. Perhaps the more telling result was the effect on the distribution of the data. This is shown in FIGS. 7 and 8.

The silver paste and firing processes used in traditional cell manufacturing are wrought with variability. Whether its screen-printing issues, furnace variability, or paste composition inconsistencies, the traditional process results in cells with a high standard deviation in the grid line resistances. The cells in this experiment started with a standard deviation of 18 milliohms prior to plating. After plating the standard deviation had dropped to 6 milliohms. So, not only did the overall resistance drop, the variability in R_{Front} was reduced dramatically.

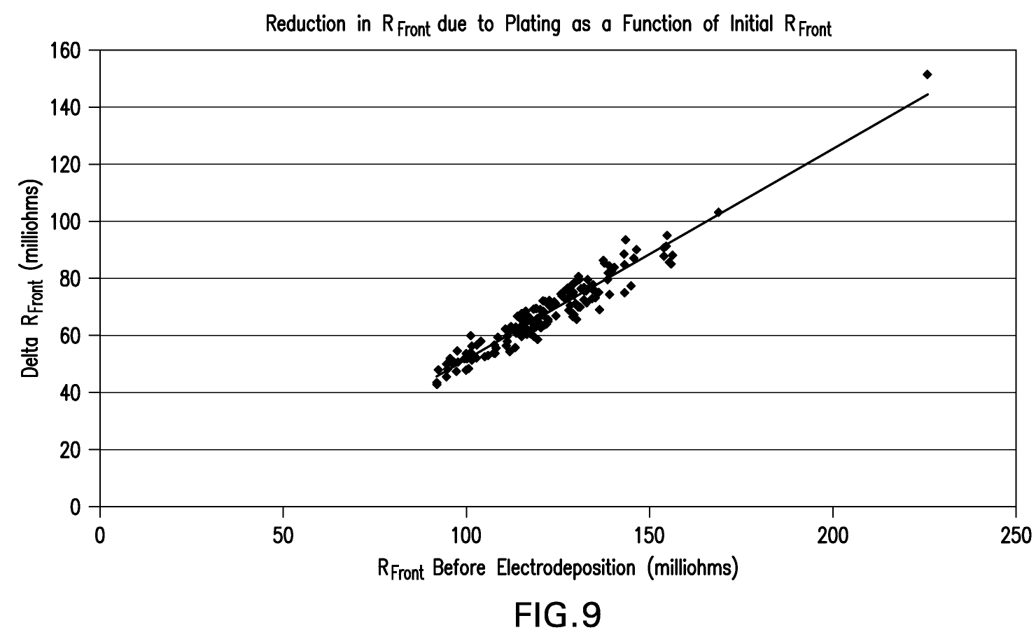

A closer look at the results on individual cells helps highlight the mechanism for improvement. If the change in the R_{Front} is plotted as a function of the initial R_{Front}, it becomes obvious that the plating process is capable of making a dramatic impact on those cells that have a high initial resistance. FIG. 9 shows that the cells with higher starting initial resistances benefited the most from the electrodeposition process which in turn resulted from the fine grained, equiaxed structure of the present invention.

What is claimed is:

1. A metallized solar cell having enhanced electrical conductivity or electrical efficiency which comprises:
a substrate that has electroplatable conductors comprising an initial conductive metallic layer on the substrate and non-electroplatable portions; and
one or more additional metal layers upon the initial conductive solar cell material to improve conductivity and increase electron or current flow, as well as reduce, minimize or prevent corrosion or oxidation of the initial conductive solar cell conductor material;
with the additional metal layer(s) optionally including an organic protective coating to minimize oxidation or other surface reactions from occurring on the conductive metallic layer or additional metal layer(s).

2. The metallized solar cell of claim 1, wherein the initial conductive layer is a silver paste comprising greater than 50% to 100% by weight silver and having a thickness of about 1 to 30 microns, or is a deposited metal layer.

3. The metallized solar cell of claim 1, wherein the one or more additional metal layers comprise silver, nickel, copper, tin, indium, gallium, selenide or alloys or combinations thereof.

4. The metallized solar cell of claim 3, wherein the additional metal layer(s) comprises a nickel layer having a thickness of 0.01 to 20 microns, a copper layer having a thickness of 0.01 to 100 microns, a tin layer having a thickness of 0.01 to 200 microns, or combinations thereof.

5. The metallized solar cell of claim 1, whereby the electroplated deposits are significantly free of residual stress, wherein the residual stress is no more than about 12,000 psi.

6. The metallized solar cell of claim 1, which further comprises an organic protective coating to minimize oxidation or other surface reactions from occurring on the conductive metallic layer or additional metal layer(s).

7. A method of making a metallized solar cell according to claim 1 which comprises:
applying an initial conductive layer on the a solar cell substrate by a metallization method to form electroplatable portions thereof; and
electroplating one or more additional metal layers upon the electroplatable portions of the substrate using cyanide-free electroplating solutions that are free of organic sulfonic acids;
and optionally applying an organic coating on the final metal layer to protect the electroplatable portion of the substrate.

8. The method of claim 7, wherein the initial conductive layer is applied by a metallization method comprising conductive metal paste screening, physical or chemical vapor deposition, or electroless or electrolytic plating.

9. The method of claim 7, wherein the initial conductive solar cell conductor metallization material is applied by conductive metal paste screening with a silver paste having a thickness of about 0.01 to 30 microns and comprising greater than 50% to 100% by weight silver.

10. The method of claim 7, wherein the additional metal layers comprise silver, nickel, copper, tin, indium, gallium, selenide, or other alloys thereof wherein the additional metal layers are applied by electroless or electrolytic plating.

11. The method of claim 7, whereby the electroplated metal layers are significantly free of residual stress, wherein the residual stress is no more than about 12,000 psi.

12. The method of claim 7, which further comprises applying an organic protective coating to minimize oxidation or other surface reactions from occurring on the conductive metallic layer or additional metal layer(s).

13. The method of claim 7, wherein the additional metal layers of the solar cell comprises a nickel layer having a thickness of 0.01 to 20 microns, a copper layer having a thickness of 0.01 to 100 microns, a tin layer having a thickness of 0.01 to 200 microns, or combinations thereof.

14. A method of enhancing the electrical conductivity or electrical efficiency of a solar cell which comprises providing electroplated metal layers that are significantly free of residual stress on a solar cell substrate thereon to form more substantial current carrying metal deposits, wherein the residual stress of the metal layers is no more than about 12,000 psi to enhance bonding of the layers and minimize loss of electrical connectivity.

15. The method of claim 14, wherein the solar cell is a “CIGS” solar cell that includes layers of copper (Cu), indium (In), gallium (Ga), and selenide (Se).

16. The method of claim 15, wherein the electroplated layers are provided by cyanide-free electroplating solutions that are free of organic sulfonic acids to further avoid “lift-offs” of the layers which break the electrical connectivity of the cell.

17. The method of claim 16, wherein the electroplated layers are provided by:
applying an initial conductive layer on the solar cell substrate by a metallization method to form electroplatable portions thereof; and
electroplating one or more additional metal layers upon the electroplatable portions of the substrate using cyanide-free electroplating solutions that are free of organic sulfonic acids;
and optionally applying an organic coating on the final metal layer to protect the electroplatable portion of the substrate.
